(19) United States
(12) Patent Application Publication
(10) Pub. No.: US 2022/0006475 A1
(43) Pub. Date: Jan. 6, 2022

(54) PERFORMANCE ENHANCEMENT OF POLAR CODES FOR SHORT FRAME LENGTHS CONSIDERING ERROR PROPAGATION EFFECTS

(71) Applicant: CANKAYA UNIVERSITESI, Ankara (TR)

(72) Inventor: Orhan GAZI, Ankara (TR)

(73) Assignee: CANKAYA UNIVERSITESI, Ankara (TR)

(21) Appl. No.: 17/296,261

(22) PCT Filed: Oct. 18, 2019
(86) PCT No.: PCT/TR2019/050878

§ 371 Date: May 24, 2021

(30) Foreign Application Priority Data
Dec. 27, 2018 (TR) 2018/20762

(51) Int. Cl. H03M 13/29; H03M 13/35; H03M 13/09; H04L 1/00

(52) U.S. Cl. CPC H03M 13/2906; H03M 13/353; H04L 1/0045; H04L 1/0041; H03M 13/09

(57) ABSTRACT

A method for performance enhancement of polar codes for short frame lengths considering error propagation effects is provided. The method inspects effects of the error propagation on a performance of the polar codes and proposes methods to alleviate degrading effects of the error propagation on a code performance for the short frame lengths.

### CROSS REFERENCE TO THE RELATED APPLICATIONS

This application is the national stage entry of International Application No. PCT/TR2019/050878, filed on Oct. 18, 2019, which is based upon and claims priority to Turkish Patent Application No. 2018/20762, filed on Dec. 27, 2018, the entire contents of which are incorporated herein by reference.

### TECHNICAL FIELD

The invention relates to a to a Performance Enhancement of Polar Codes for Short Frame Lengths Considering Error Propagation Effects and inspect the effects of error propagation on the performance of polar codes and propose some methods to alleviate the degrading effects of error propagation on the code performance for short frame lengths.

### BACKGROUND

Polar codes are the first class of channel codes whose performances are mathematically provable, and they are designed using the fundamental concepts of information theory [1]. Polar codes are decoded in a sequential manner using successive cancelation algorithm whose details can be found in [1]. Polar codes show good performance at large frame lengths. On the other hand, they suffer from low performance at short codeword lengths. However, many practical communication systems such as wifi and gsm employ short frame sizes for communication. After the introduction of successive cancelation decoding of polar codes, improved decoding algorithms employing the exchange of soft information, called belief propagation algorithms, in a sequential manner are proposed. One such an algorithm is proposed in [2] where additional structures in polar encoding unit are introduced and using these units soft decoding is performed at the decoder side. To improve the low performance of polar codes, the list and stack decoding algorithms are proposed in [3], [4], [5]. Although, list and stack decoding algorithms have better performance than that of the classical successive cancelation method [1], they require much higher computation, i.e., they have high decoding complexity, and this limits their use in practical communication systems. Although low complexity and improved versions of the successive cancelation algorithm are introduced, degrading effects of error propagation due to the sequential nature of the SC algorithms still stays as a major factor for low performance.

Patent application [6] inherits dividing information set into subgroups (subsequences) and applies CRC in the transmitter part. In the receiver, subgroups are decoded in a head-to-tail manner. In [7], a number of CRC sequences are calculated for a number of subsequences in the transmitter instead of one CRC calculation for all information bits. Then successive cancellation list is applied with CRC check in the receiver. In patent application [8], CRC aided successive cancellation list (SCL) decoding is proposed. Idea of using CRC in polar codes emerged during developing list decoding. In list decoding, there are n different decoders that works in parallel. Each parallel branch decodes according to best possible candidate. At the end of the decoding cycle, branch that checks CRC truley, gives the best result. Patent applications [9-10] offer a CRC coding method capable of remove codewords in the range of d Hamming distance from transmission codeword while adjusting the value of parameter d. In order to accomplish this, the CRC coding is applied to some bits of K information bits other than all of K information bits.

### SUMMARY

This invention relates to a Performance Enhancement of Polar Codes for Short Frame Lengths Considering Error Propagation Effects.

This invention proposed a new approach for the alleviation of error propagation that occurs in successive cancelation decoding of polar codes.

Single errors occurring at even indexed bits has more degrading effects than the single errors occurring at odd indexed bit locations. The proposed approach uses a training based approach to determine the most likely first erroneous bit locations, and employ cyclic codes for the mostly likely even erroneous bit locations. Syndrome decoding is performed at the receiver side in case of error occurs at determined most likely erroneous bits. It is shown via computer simulations that the proposed approach shows much better performance than that of the classical successive cancelation algorithm with a negligible extra overhead, and significant improvements is observed in performance for short frames sizes which are used in practical communication systems.

Another aspect of the invention, wherein the rate of the cyclic codes are R=0.5 For the chosen data bits at the even indices.

### BRIEF DESCRIPTION OF THE DRAWINGS

The figures used to better explain performance enhancement of polar codes for short frame lengths considering error propagation effects developed with this invention and their descriptions are as follows:

FIG. 1: Polar Encoder and Decoder Units.

In FIG. 1 a, b are data bits, c, d are code bits, e, d are estimated code bits and a, b are estimated data bits.

FIG. 2: Polar Encoder for N=4.

In FIG. 2 u₁, u₂, u₃, u₄ are data bits, x₁, x₂, x₃, x₄ are code bits, W represents a channel, and y₁, y₂, y₃, y₄ are channel outputs.

FIG. 3: Tree representation of polar decoders for N=2.

In FIG. 3 â, \hat{b} and ĉ are bits.

In FIG. 3 u₁, u₂, u₃, u₄ are data bits estimated, x₁, x₂, x₃, x₄ are estimated code bits, W represents a channel, and y₁, y₂, y₃, y₄ are channel outputs.

FIG. 4: Polar decoding path of u₃ and its tree representation for N=4.

In FIG. 4 u₁, u₂, u₃ are data bits estimated, x₁, x₂, x₃, x₄ are estimated code bits, g₁, g₂ are bits

FIG. 5: Polar decoding path of u₈ and its tree representation for N=8.

In FIG. 5, u₁, . . . , u₈ are estimated data bits, x₁, . . . , x₈ are estimated code bits, g₁, . . . g₄ and h₁, h₂ are bits

FIG. 6: Error propagation vs error location, Rate=0.5, N=1024, α=0.5

FIG. 7: Frequency graph for the index of first erroneous bit, N=32, BEC with α=0.5 and Rate=0.5 is used.

FIG. 8: Frequency graph for the index of first erroneous bit, N=64, BEC with α=0.5 and Rate=0.5 is used.

FIG. 9: Communication system with CRC.

CRC means cyclic redundancy check.

FIG. 10: BER performance comparison in BEC where α=0.5, N=32.

BEC means binary erasure channel.

FIG. 11: BER performance comparison in BEC where α=0.5, N=64.

### DETAILED DESCRIPTION OF THE EMBODIMENTS

To better explain a performance enhancement of polar codes for short frame lengths considering error propagation effects developed with this invention, the details are as presented below.

Polar codes are decoded in a sequential manner using successive cancelation algorithm introduced in Arikan's original work [1]. The sequential nature of the decoding process suffers from error propagation. In this paper, we inspect the effects of error propagation on the performance of polar codes and propose some methods to alleviate the degrading effects of error propagation on the code performance for short frame lengths.

Successive Cancelation Decoding of Polar Codes with Tree Structure:

Polar encoder and decoder structures are as presented below, then provide information about tree representation of polar decoder structure.

Kernel Polar Encoder Structures and Basic Formulas:

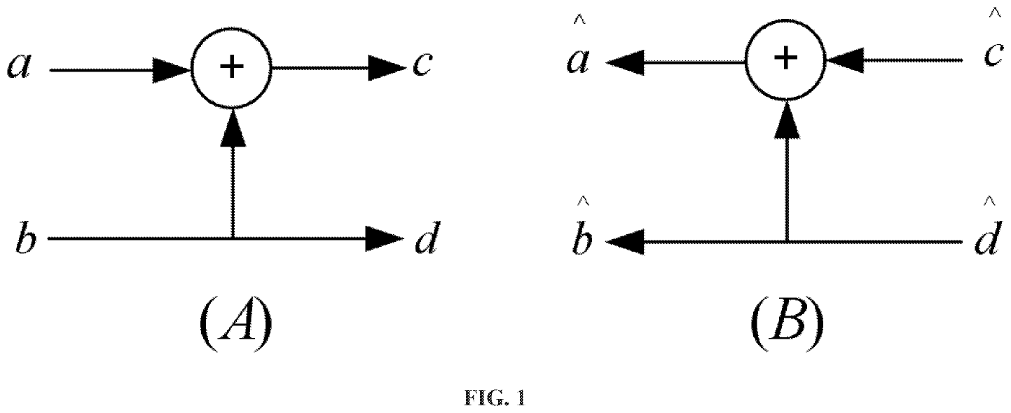

The kernel polar encoder and decoder structures are depicted in FIG. 1. From the decoder unit in FIG. 1, we can

write

â=ĉ⊕\hat{d} \hat{b}=\hat{d} (1)

from which, it can be shown that we can calculate

$$\begin{matrix}LR ( \hat{a} ) = \frac{p ( \hat{a} = 0 )}{p ( \hat{a} = 1 )} \\ as & ( 2 ) \\ LR ( \hat{a} ) = \frac{1 + L R ( \hat{c} ) L R ( \hat{d} )}{L R ( \hat{c} ) + L R ( \hat{d} )} . & ( 3 )\end{matrix}$$

The value of â can be decided using (3). After deciding the value of â, we can start to decoding of b and the likelihood ratio for \hat{b} can be found as

$$L R ( \hat{b} ) = \frac{p ( \hat{b} = 0 )}{p ( \hat{b} = 1 )} \to L R ( \hat{b} ) = L {R ( \hat{c} )}^{1 - 2 \hat{a}} L R ( \hat{d} ) . \qquad ( 4 )$$

The formulas in (3) and (4) are expressed in a recursive manner in [1] as

$$\begin{matrix}{L}_{N}^{( 2 i - 1 )} ( {y}_{1}^{N} , {\hat{u}}_{1}^{2 i - 2} ) = \frac{{L}_{N / 2}^{( i )} ( {y}_{1}^{N / 2} , {\tilde{u}}_{1 , o}^{2 i - 2} ⊕ {\tilde{u}}_{1 , e}^{2 i - 2} ) {L}_{N / 2}^{( i )} ( {y}_{N / 2 + 1}^{N} , {\tilde{u}}_{1 , e}^{2 i - 2} ) + 1}{{L}_{N / 2}^{( i )} ( {y}_{1}^{N / 2} , {\tilde{u}}_{1 , o}^{2 i - 2} ⊕ {\tilde{u}}_{1 , e}^{2 i - 2} ) + {L}_{N / 2}^{( i )} ( {y}_{N / 2 + 1}^{N} , {\tilde{u}}_{1 , e}^{2 i - 2} )} \\ and & ( 5 ) \\ {L}_{N}^{( 2 i )} ( {y}_{1}^{N} , {\hat{u}}_{1}^{2 i - 1} ) = {[ {L}_{N / 2}^{( i )} ( {y}_{1}^{N / 2} , {\tilde{u}}_{1 , o}^{2 i - 2} ⊕ {\tilde{u}}_{1 , e}^{2 i - 2} ) ]}^{1 - 2 {\tilde{u}}_{2 i - 1}} {L}_{N / 2}^{( i )} ( {y}_{N / 2 + 1}^{N} , {\tilde{u}}_{1 , e}^{2 i - 2} ) & ( 6 )\end{matrix}$$

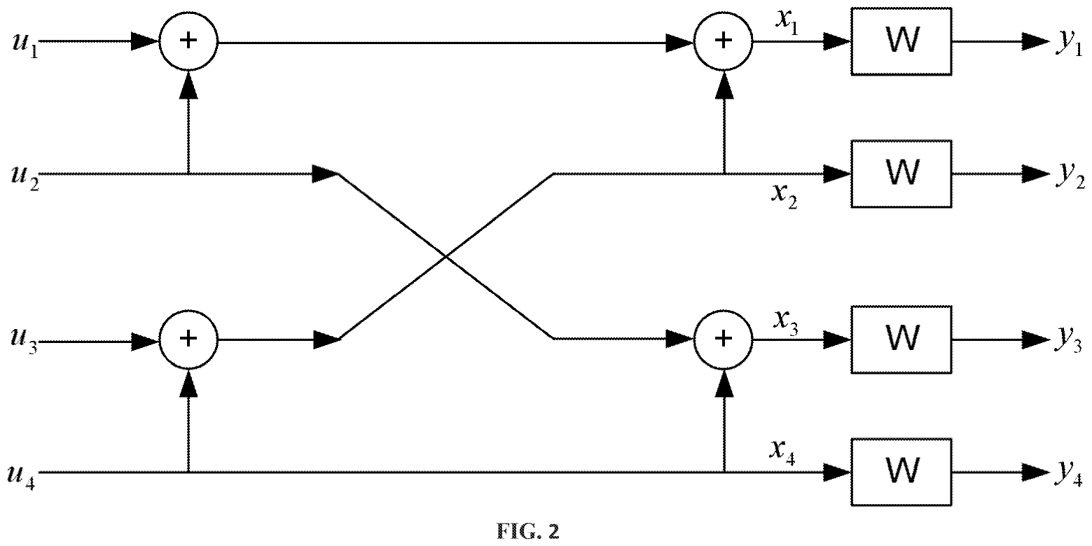

The polar encoders are constructed assembling the kernel units depicted in FIG. 1 in a Butterfly structure. The polar encoder with discrete memoryless channels for N=4 is shown in FIG. 2.

Tree Structure for Polar Decoder:

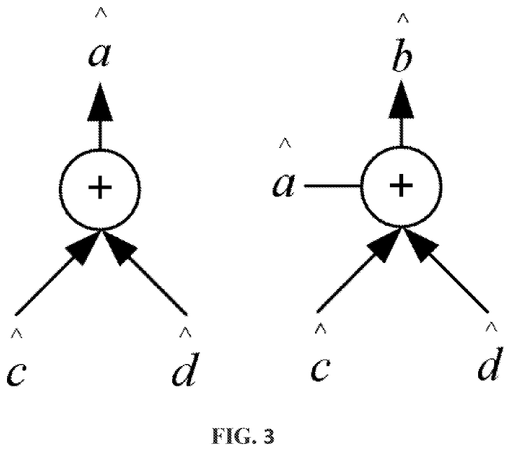

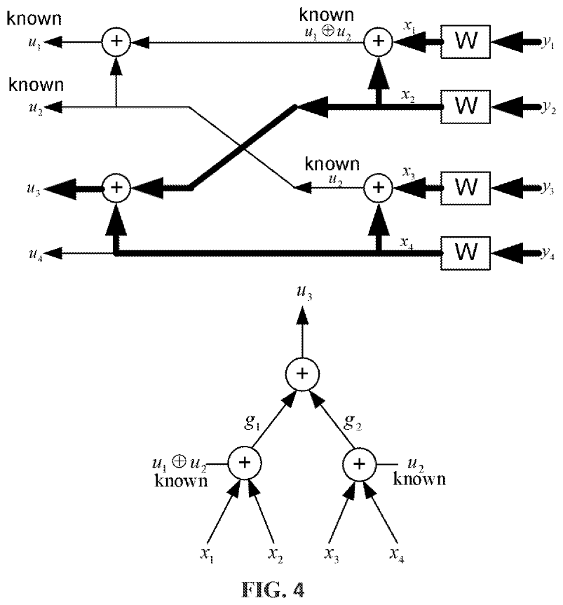

The decoding operation for N=2 can be illustrated using simple trees as in FIG. 3 where the left tree corresponds to the decoding of a, i.e., the first bit, and the right tree correspond to the decoding of b, i.e., the second bit. And as can be seen from the decoding tree of b, the decision result of the first bit is used as a node-bit. Now assume that N=4, and third-bit is to be decoded. The decoding path of the third-bit for N=4 and its tree representation is shown in FIG. 4. It is clear from the tree graphs depicted in FIG. 4 that the nodes in the decoder tree may have some bits assigned to them depending on the index of the current-bit to be decoded. The tree consists of levels each of which has an index. The top-most level has the index value 0, and the bottom-most level has an index value n=log₂ N. The topmost level has 2⁰=1 node, and the bottom most level has N=2ⁿ nodes. In fact, the level with index m, where m ∈ [0 . . . n], has 2^{m} nodes.

Determination of Node-Bits: In this subsection, we propose a short method to determine the values of node-bits in the decoder tree used for the decoding of bit uₖ₊₁ where k ∈ [0 . . . N−1]. For this purpose, we first determine the nodebits, then calculate the likelihoods of the nodes starting from the bottom ones till the top-most node. For the determination of the node bits, we first write the integer k as sum of powers of 2, i.e.,

$$k = {\sum }_{i} {2}^{i} \qquad ( 7 )$$

where i refers to the levels whose nodes have assigned bits. Once we determine the level indices i, we partition the previously decoded bit stream starting from the last bit into consecutive sub-streams ūᵢ containing 2ⁱ bits, and the node bits are determined using

n̅ᵢ=ūᵢ×Gᵢ (8)

where Gᵢ is the sub-generator matrix of size 2ⁱ×2ⁱ.

Example: Assume that N=16 and we want to decode u₁₃ and the previous 12 decoded bits are b̅=[100101110011]. We can write 12 as 12=2³+2² and obtain the sub-streams as b̅₂=[0011] and b̅₃=[10010111]. Then the node bits are calculated as

n̅₂=ū₂×G₂→n̅₂=[0011]×G₂

n̅₃=ū₃×G₃→n̅₃=[10010111]×G₃

Sequential Decoding and Error Propagation:

In successive cancelation decoding of polar codes, for the decoding of (k+1)^{th}-bit we benefit from two kinds of information sources. One is the soft information obtained from the received (k+1)^{th}-signal, i.e., soft information obtained from the output of the (k+1)^{th}-channel. The other is the k decision results obtained from the decoding of the previous k bits. This means that the wrong decisions made for the decoding of previous bits affect the decoding of current bit, i.e., bit error propagate throughout the decoding operation.

Bit Errors in Even and Odd Locations:

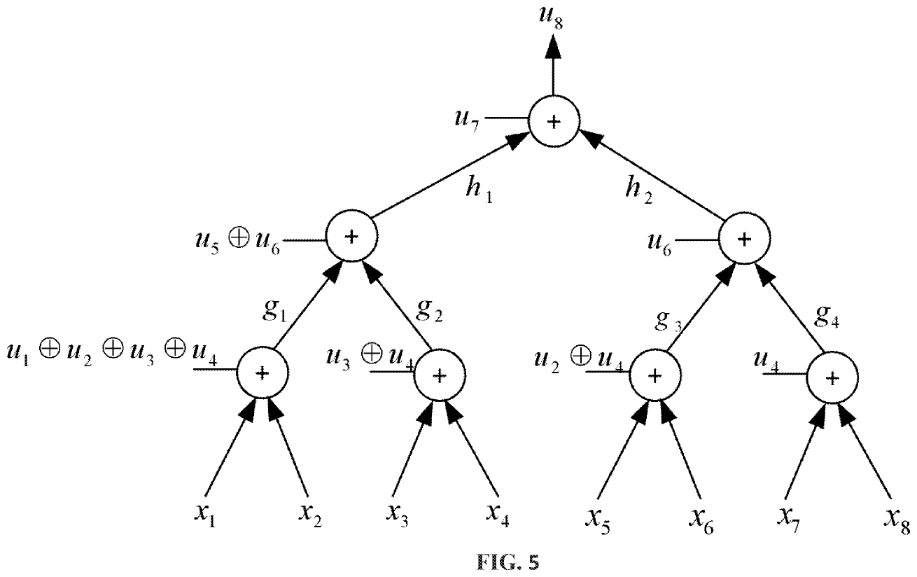

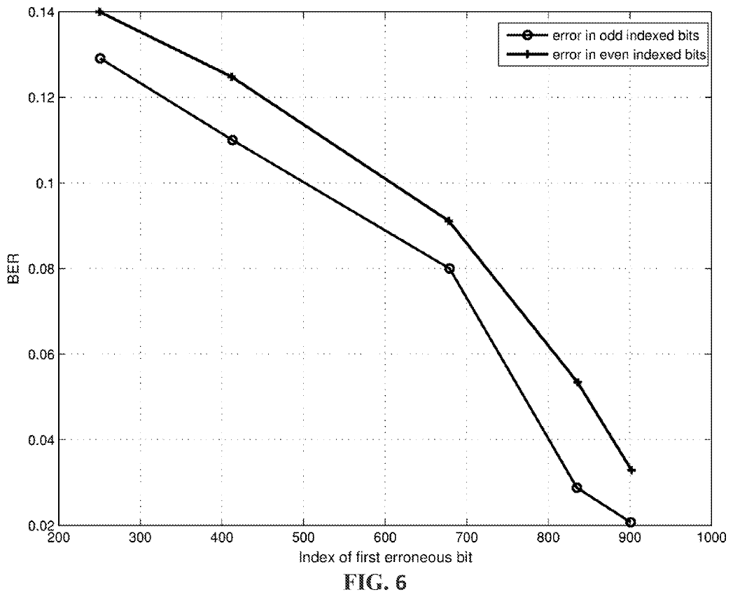

Decoding tree can help us to visualize the distribution of the previously decoded bits to the nodes. For instance, for the decoding of u₈, the distribution of 7 decoded bits u₁, u₂, . . . , u₇ can be achieved using the sub-generator matrices G₁, G₂, G₄, and we get the decoding tree as in FIG. 5. When FIG. 5 is inspected in details, we see that even indexed bits appears at every node-bit combinations, on the other hand, odd indexed bits appear only in some of the node-bit combinations. In addition, the bit u₄ appears in every node bit combinations at level-2. It is obvious that a wrong decision on the value of bit u₄ affects the probability calculation of the all the nodes of level-2, and nodes at upper levels receive wrong probability values. To test the effects of even and odd indexed bit errors, we introduced single bit errors without BEC, and obtained BER graphs via computer simulations. The obtained graph is depicted in FIG. 6. It is clear from FIG. 6 that the even indexed bit errors have more degrading effects on code performance.

Alleviation of Error Propagation Via Training Based Approach:

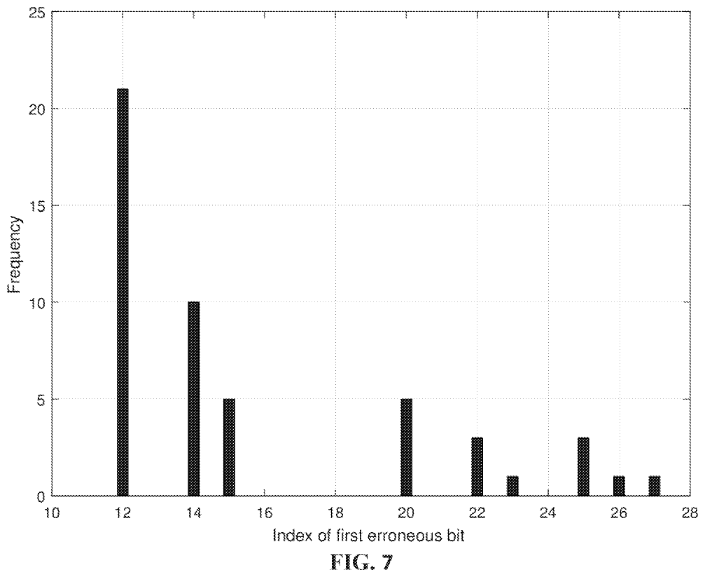

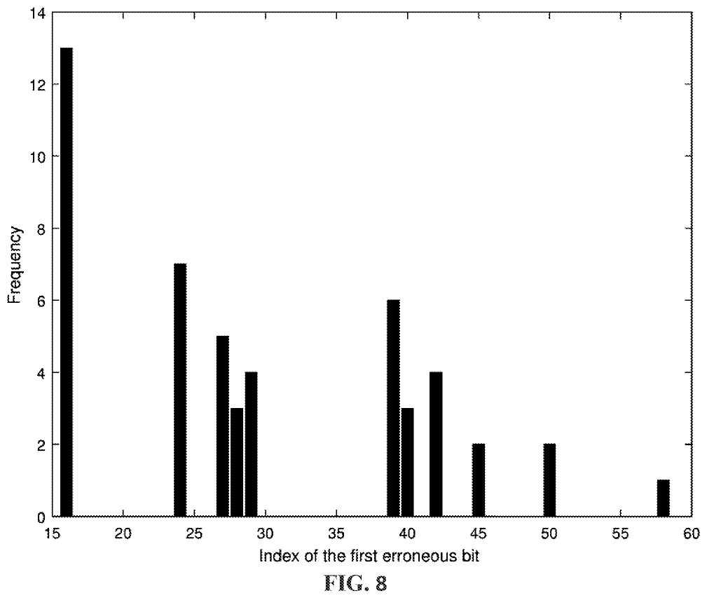

In this sub-section, we introduce a training based approach for the alleviation of error propagation problem. In our proposed approach, we first extract some statistical information for the most probable error locations. For this purpose, we transmit 50 frames and record the index of first erroneous bit. The statistical data for N=32, N=64 and rate R=0.5 are plotted as histogram as in FIGS. 7 and 8 from which we see that the first erroneous bits usually appear at the small capacity channels, and they correspond, in general, to the first half of the data block. For different rates the statistical information is extracted via training approach. Since erroneous bits occurring at even indexes have more degrading effects than the erroneous bits at odd indexes, for N=32 for the first 4 data bits, and for N=64 for the first 6 data bits, which are most probably to the errors, we employ cyclic codes with generator polynomials g₁(x)=x₆+1, g₂(x)=x₄+1. The rate of the cyclic codes are R=0.5. The parity bits obtained from the cyclic codes are concatenated to the end of the polar codes as side information.

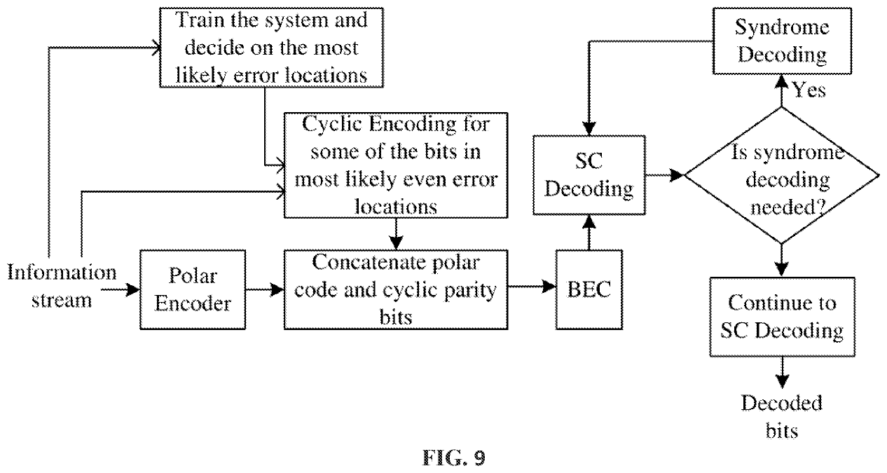

We did our simulations for BEC with erasure probability α=0.5. The even indices for the data bits for rate R=0.5 and N=32 are chosen as [12, 14, 20, 22], and they are chosen for rates 0.43, 0.37, 0.32 as [14, 16, 20, 22], [16, 22, 26, 28], [16, 24, 26, 28] respectively. In a similar manner using a training based approach, the even indices for rate R=0.5 and N=64 are chosen as [16, 24, 28, 40, 50, 58], and they are chosen for rates 0.4, 0.37, 0.32 as [24, 28, 30, 40, 50, 52], [28, 30, 40, 46, 50, 52], [30, 40, 44, 46, 50, 52] respectively. For the chosen data bits at the even indices, we employed cyclic code with rate R=0.5, and the parity bits are concatenated to the end of the polar codeword. At the received side, SC(successive cancelation) algorithm is run, and when the decoding of the chosen data bits at even indices are complete, a check is performed for the cyclic parity bits. If any error in the chosen bits are detected, syndrome decoding is performed for the chosen data bits and decoding operation is continued for the rest of the bits. The proposed system is depicted in FIG. 9.

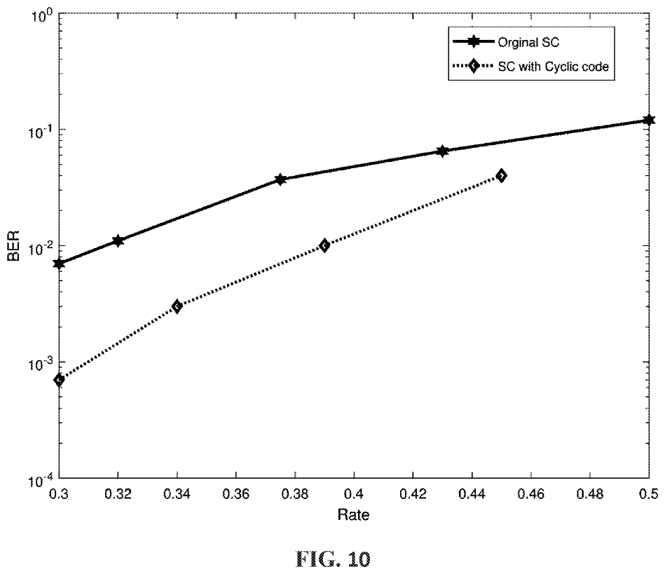

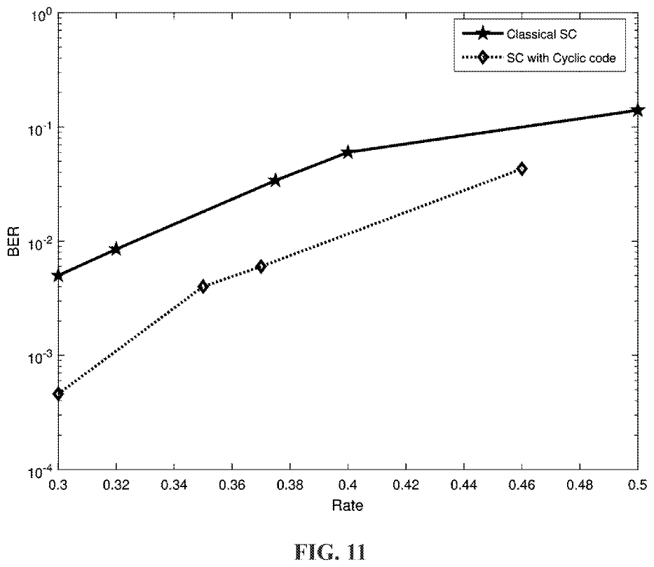

The simulation results for binary erasure channel are depicted in FIGS. 10 and 11 where it is seen that the proposed approach shows better performance than that of the classical successive cancelation algorithm proposed in [1]. This is the expected result, since employing cyclic codes for the most probable even error locations, we alleviate the degrading effect of error propagation, and even for very short frame lengths we obtain significant performance improvement for short sizes.

The method of an a performance enhancement of polar codes for short frame lengths considering error propagation effects comprising the steps of;
Employing of cyclic code with rate for the chosen data bits at the even indices, concatenating of the parity bits to the end of the polar codeword,
At the receiver side, running of SC algorithm decoding of the chosen data bits at even indices,
At the receiver side, when the decoding of the chosen data bits at even indices are complete, performing of the check for the cyclic parity bits,
If any error in the chosen bits are detected, syndrome decoding is performed for the chosen data bits and,
Decoding operation continues for the rest of the bits.

### REFERENCES:

[1] E. Arikan, “Channel polarization: A method for constructing capacity achieving codes for symmetric binary-input memoryless channels,” IEEE Trans. on Inf. Theory, vol. 55, no. 7, pp. 30513073, July 2009.

[2] U. U. Fayyaz and J. R. Barry, “Low-complexity soft-output decoding of polar codes,” in IEEE Journal on Selected Areas in Comm., vol. 32, no. 5, May 2014.

[3] I. Tal and A. Vardy, “List decoding of polar codes,” in Proc. of IEEE Int. Symp. on Inf. Theory, 2011, pp. 15.

[4] K. Niu and K. Chen, “Stack decoding of polar codes,” Electronics Letters, vol. 48, no. 12, pp. 695697, June 2012.

[5] K. Chen, K. Niu, and J. Lin, “Improved successive cancellation decoding of polar codes,” IEEE Trans. on Communications, vol. 61, no. 8, pp. 31003107, August 2013.

[6] Univ Shenzhen, “LSC-CRC Decoding-Based Segmented Polar Code Encoding And Decoding Method And System”, WO2018133215 (A1), Jul. 26, 2018.

[7] Qualcomm Inc, “Enhanced Polar Code Constructions By Strategic Placement Of CRC Bits”, US2018205498 (A1), Jul. 19, 2018.

[8] Qualcomm Inc, “CRC Bits For Joint Decoding And Verification Of Control Information Using Polar Codes”, WO2018107680 (A1), Jun. 21, 2018.

[9] Huawei Technologies, “Decoding Method And Decoding Apparatus For Polar Code Concatenated With Cyclic Redundancy Check”, EP2802080, May 25, 2012.

[10] Sungkyunkwan University Research & Business Foundation, “Encoding Method And Apparatus Using CRC Code And Polar Code”, US2014/0173376 (A1), Jun. 19, 2014.

What is claimed is:

1. A method for a performance enhancement of polar codes for short frame lengths considering error propagation effects, comprising the steps of:
extracting statistical information for most probable error locations, transmitting a number of frames and recording an index of a first erroneous bit when a Successive Cancellation (SC) algorithm is employed, and repeating the steps of extracting, transmitting and recording for a transmission of a number of random data frames, wherein the number of random data frames are 50 or 100 frames or more,
from the index of first erroneous bit, choosing even indices,
employing a cyclic code with a rate for chosen data bits at the even indices, concatenating parity bits to an end of a polar codeword to obtain cyclic parity bits,
at a receiver side, running the SC algorithm and decoding the chosen data bits at the even indices when a turn of the even indices comes,
at the receiver side, when the decoding of the chosen data bits at the even indices are complete, performing a check for the cyclic parity bits,
when any error in the chosen data bits are detected, performing a syndrome decoding for the chosen data bits.
